(19) United States
(12) Patent Application Publication
(10) Pub. No.: US 2003/0059957 A1
(43) Pub. Date: Mar. 27, 2003

(54) Chip sorting unit used for apparatus for inspecting surface mounted chip

(76) Inventor: Peter W. Newman, Taegu (GB)

Correspondence Address: VOLPE AND KOENIG, P.C., SUITE 400, ONE PENN CENTER, 1617 JOHN F. KENNEDY BOULEVARD, PHILADELPHIA, PA, 19103, US

(21) Appl. No.: 10/220,138

(22) PCT Filed: Nov. 7, 2001
(86) PCT No.: PCT/KR01/01886

(30) Foreign Application Priority Data
Dec. 29, 2000 (KR) 2000/0085406

(51) Int. Cl. H01L 21/00

(52) U.S. Cl. 438/1

(57) ABSTRACT

Handling of small delicate components at a high speed is a difficult engineering challenge. The newly invented mechanism can reliably and accurately sort components into two more groups at a high speed without damaging the component.

### TECHNICAL FIELD

Surface Mount 6-side Component Handling, Vision Inspection and Sorting System

### BACKGROUND ART

The invention is a part of system which can accurately and reliably inspect the surface of surface mount electrical components such as MLCC (Multi-Layer Ceramic Capacitor). The system consist of the housing block and the rotating assembly that can supply compressed air and vacuum, the lower and upper discs along with the a set of cameras. The invention, the sorting mechanism which sorts the passes and fails, is located below the lower disc and is activated via solenoids. Spring 1 is located between the Body 1&3 and Body 1&2; and Spring 2 is located between Body 2 and 3. To activate Spring 1 and Spring 2, the solenoid attached to Body 1 (202) and Body 3 are activated, respectively.

The invention is designed to accurately and reliably inspect the surface of surface mount electrical components such as MLCC (Multi-Layer Ceramic Capacitor).

As the demand for faster and more compact computer increases, the computer industry is demanding smaller and efficient electrical components. In addition, the trend in the high tech consumer electronic goods is becoming smaller thus smaller electrical components.

Today these electrical components such as MLCCs are becoming so small in the units of tenth of millimeters. In a typical computerized product, a several hundred to thousand components are used in a component. However, small component size makes it quite difficult for human eyes to inspect and sort defective components from the good.

The most commonly used inspection system employs a rotating glass plate to position and inspect the component. As the glass plate is rotated, the components are placed on the outer edge of the glass plate. At this point, the system takes a picture and analyzes the component for any defect.

Previously the sorting mechanism employed compressed air to blow the components. This mechanism is inefficient when the sorting speed increases. Moreover, the mechanism cannot sort untested components separately. Therefore, the invention is designed to overcome these challenges—high speed inspection. Moreover, the invention can sort untested components from other passes and fails.

### DISCLOSURE OF INVENTION

To achieve the stated objective, the vision inspection system consist of housing block, which two discs can be attached on the face and rotated, the compressed air and vacuum supply system, and a set of camera. In addition, the sorting mechanism is attached which is located below the lower disc. Collection tray bins are also supplied which are located below the sorting mechanism to collect the sorted components.

Spring 1 is located between the Body 1&3 and Body 1&2; and Spring 2 is located between Bodt 2 and 3. To activate Spring 1 and Spring 2, the solenoids attached to Body 1 (202) and Body 3 are activated, respectively.

To achieve the stated objective, the vision inspection system consist of housing block, which two discs can be attached on the face and rotated, the compressed air and vacuum supply system, and the set of camera. In addition, the component feeder is attached to the system to continuously supply the component reliably.

The discs consist of two round flat plate put together. The disc has a number of slots through which the vacuum is supplied. Air holes equal to the number of vacuum slots are found on one side of the disc through. On the edge of disc is the v-slot in which the components are placed. Air holes are placed approximately 0.03 to 0.05 mm apart.

To supply the vacuum to the air slots on the disc, the housing block houses the compressed air and vacuum chambers Please refer to the attached Fig. FIG. 1 is a side view of the vision inspection machine while FIG. 2 is the frontal view. On top of base (2) is the fixed housing block (4) which can be rotated and is connected to lower and upper discs (14, 16). Attached to the upper disc (14) is the feeder (12). Near the discs are the four cameras (18a, 18b, 18c, 18d).

Inside the housing block (4) is the rotational axle (42) which is connected to moor and vacuum supply unit, and compressed air supply unit. Solenoid sorting mechanism (20) is located below the lower disc. Attached to the solenoid sorting mechanism (20) is the guide block (50) which directs the sorted components to the collection bins.

FIG. 3 is a schematic diagram of the lower and upper discs (14, 16). The Fig details the connecting point of the lower (14) and the upper disc (16). The disc contains 50 vacuum slots (44) which are directed to the center of the disc. The two plates forming the disc are held air tight to prevent vacuum leakage. At the top where the two plates are forging is the v-slot where the 6-side component can be placed.

The disc is attached to the rotational axle (42) which is attached to the protrusion (6) of the housing block (42). The upper disc (14) rotates in counter-clockwise direction while the lower disc (16) rotates in clockwise direction. FIG. 3 only contains simplified a diagram of the main plate.

FIG. 4 contains a schematic diagram of the upper and lower discs and housing blocks. The protrusions (6) of the housing block (4) is in contact with 50 air holes (62) located on the surface of the supporting plate on the discs (14, 16). The holes (44) are connected to the vacuum chambers located inside the discs which are connected to the vacuum slots (62). As shown in the Fig, the distance between each air hole is approximately 0.03 to 0.05 mm. FIG. 5 is a view of compressed air/vacuum separation chamber insider the housing block. Air/vacuum separation chamber (64) inside the housing block (4) is connected to the compressed air supply via air duct (42).

As shown in FIGS. 1 and 2, the cameras (18a, 18b, 18c, 18d) are positioned around the discs (14, 16). The components supplied to the upper disc (16) are placed on the v-slot, exposing the two sides. The camera (18a, 18b) takes the picture of the two exposed sides. As the upper disc (16) rotates to the bottom, the component is transfer to the lower disc (16) and placed on the v-slot of the lower disc. As the disc rotates, cameras (18c, 18d) takes the picture of the two exposed surface of the component

Components (1) being supplied continuously through the feeder (12) on to the rotating disc (14) and placed on the v-slot evenly. The components are located at the tip of the vacuum channels (46). Vacuum is supplied to the channels (46) which are connected to the air duct (44) and vacuum slots. Therefore, the components are held by the vacuum and are able to rotate with the disc without falling off the disc surface.

After a picture of the exposed side of the components is taken, the component (1) located on disc (14) rotates in the counter-clockwise direction until it reaches the lowest point. At this point, the vacuum holding the component ceases to be supplied from the vacuum channel (46). As the disc (14) rotates the air holes (44) on the side of the disc (14) are in contact with the vacuum slot located on the surface of the protrusion (6) of the housing block (4). As the component reaches the lowest point, the air ceases to be supplied to air hole (44) since it reaches the air/vacuum separation chamber. At this point, the component becomes detached from the vacuum channel (46), and transfers to the edge of lower disc (16). As the component continues to rotate the camera takes the picture. As the vacuum is used most of the contaminants are removed.

Moreover, the component position is consistently accurate and reliably. There is a little possibility for friction or collision with another components.

Solenoid sorting mechanism (20), as described in FIGS. 6 and 7, is located in the center area between Body 1 and 3 (202, 204, 206). Leap spring 2 (216) is located between the Body 2 and 3 (204, 206) while the leap spring 1 (214) is activated via the solenoid (210) attached to the body 1 (202). The solenoid 2 (216) is activated by the solenoid (212) attaché to the body 3 (206). Alignment pin (208) is located between Body 1 and 3 (202, 204, and 206).

As described in FIG. 8, when the component is determined to be “pass” then the solenoid 2 (212) pushed the leap spring 1 (216) toward the leap spring 1 (214). At this time the component (1) located at the lowest point of the lower disc (16) falls off the disc as a result of compressed air blown through the air channel. The path of falling component (1) is directed by the leap spring 2 (216) and is collected in the collection bin (52′).

As described in FIG. 9, when the component is determined to be “fail” then the solenoid 1 (210) pushed the leap spring 1 (214) toward the leap spring 2 (216). At this time the component (1) located at the lowest point of the lower disc (16) falls off the disc as a result of compressed air blown through the air channel. The path of falling component (1) is directed by the leap spring 1 (214) and is collected in the collection bin (56′).

The untested components as described FIG. 10 falls between the leap springs which does not move as a result of the solenoid 1 and 2 (210, 212) not activated. Therefore the untested component (1) is collected in the collection bin (54′).

As described the components after undergoing a vision inspection are sorted and collected in the appropriate collection bins. Since the mechanism does not exert any force to the component but uses gravitational force, the component is not damaged. The solenoid activated leap spring construction is more efficient design to increase the sorting speed.

### BRIEF DESCRIPTION OF DRAWINGS

FIG. 1 is a side view of vision inspection machine.

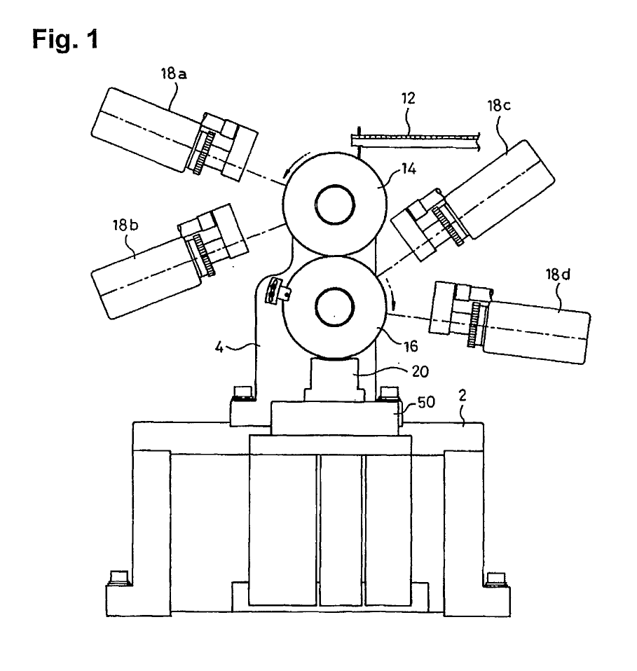

FIG. 2 is a schematic view of housing block and the upper and lower discs.

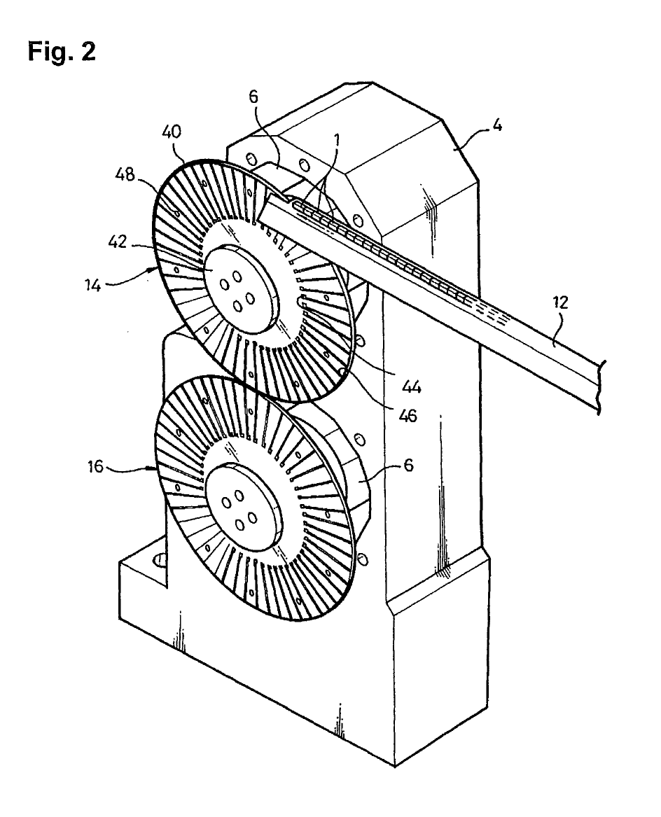

FIG. 3 is a view of joining area of discs and the housing block.

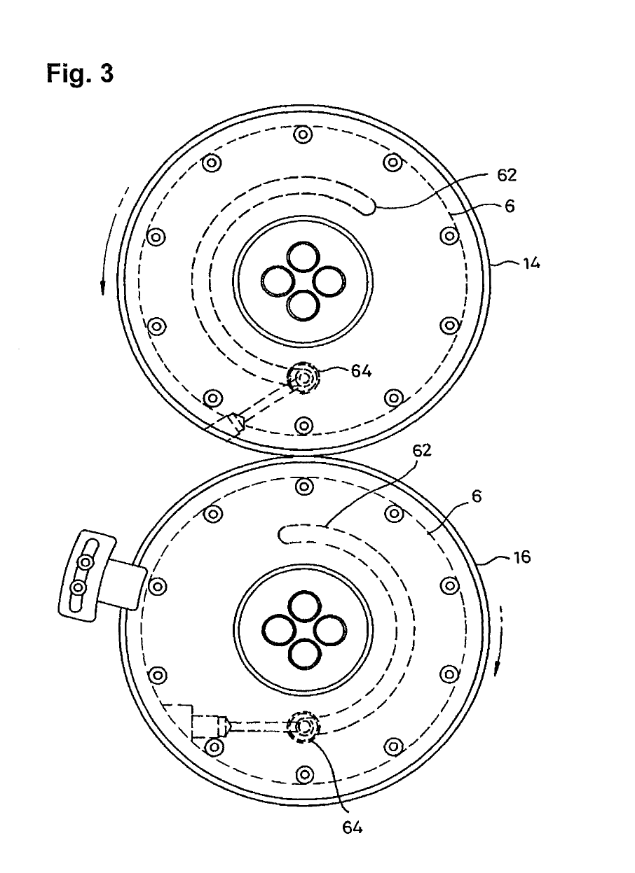

FIG. 4 is an enlarged view of the component placed on the edge of the disc.

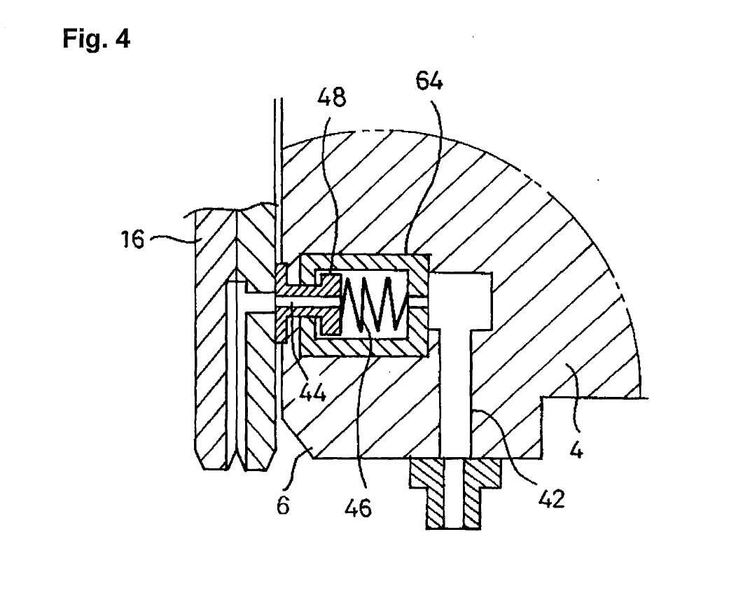

FIG. 5 is a internal view of air/vacuum separation chamber.

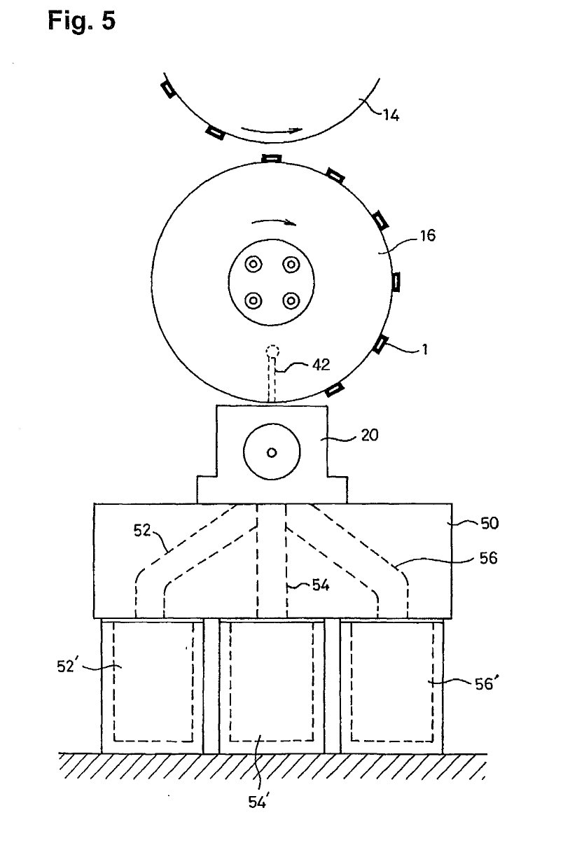

FIG. 6 is a perspective view of the inspection system.

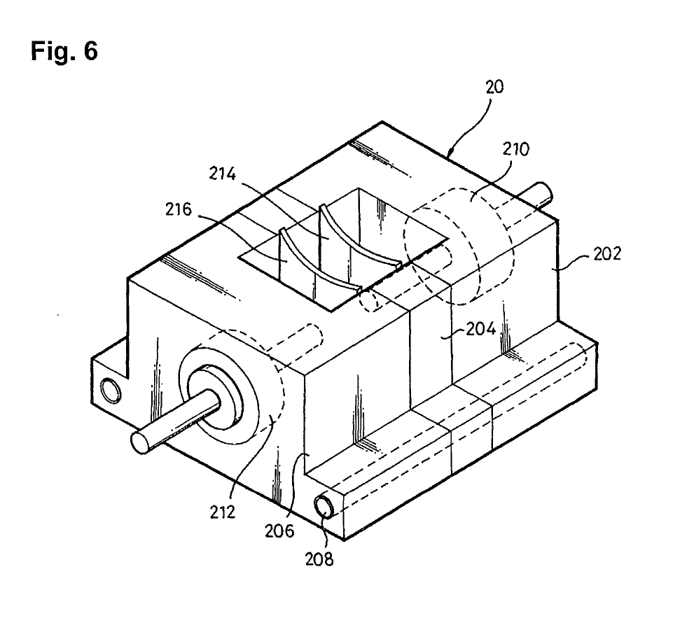

FIG. 7 is a schematic view of FIG. 6.

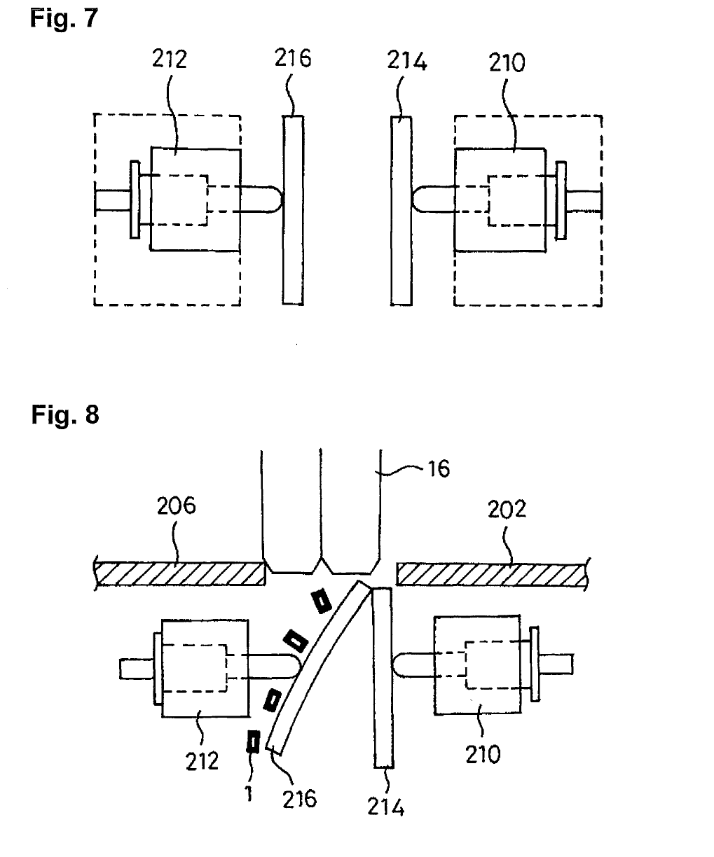

FIG. 8 thru FIG. 10 details the mechanical operation of components being sorted in the ejector system—FIG. 8 is when the component is Good; FIG. 9 when Bad; FIG. 10 when No Test.

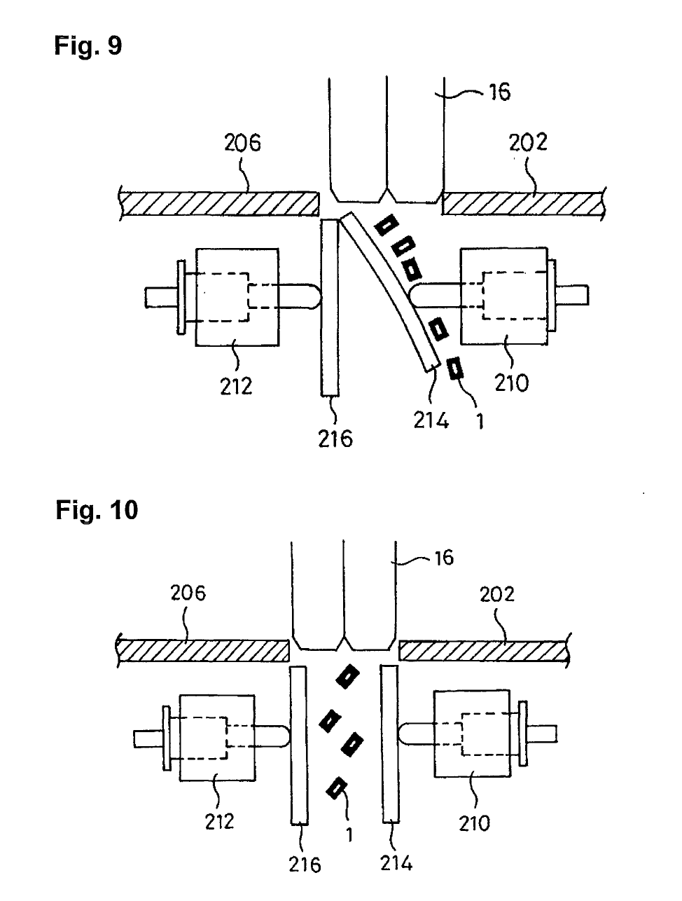

### COMPONENTS ON THE DRAWINGS

2: Base

4; Housing Block

12: Feeder

14, 16: Lower and Upper Disc

18a, 18b, 18c, 18d: Cameras

20: Solenoid Sorting Mechanism

44: Air Hole

50: Guide Block

62: Semi-circular vacuum slot

64: Air/Vacuum Separation Chamber

210, 212; Solenoid

214, 216: Leap Spring

### BEST INVENTION FOR CARRYING OUT THE INVENTION

The mechanism employs solenoids and leap springs to sort the tested components.

The mechanism employs the guide block and the collection tray bin.

Spring 1 is located between the Body 1&3 and Body 1&2; and Spring 2 is located between Body 2 and 3. To activate Spring 1 and Spring 2, the solenoid attached to Body 1 (202) and Body 3 are activated, respectively.

1. The vision inspection system that is consist of the housing block, the rotational axle that is housed inside the housing block, the disc which the vacuum and compressed air are supplied via the housing block, and the cameras positioned near and around the upper and lower discs, is complemented by the sorting mechanism that employs solenoids and leap springs to sort the tested components. The sorting mechanism is located below the lower disc of the system.

2. In connection with claim 1, the components that have been inspected are guided by the guide block and are collected in the collection tray bins. The collection bins are located below the guide block.

3. In connection with claim 1, the leap spring 1 is located between the Body 1 or 3 and Body 1 or 2; and the leap spring 2 is located between Body 2 and 3. To operate the leap spring 1, the solenoid attached to Body 1 (202) is activated. To operate the leap spring 2, the solenoid attached to Body 3 is activated. After visually inspecting small components, the mechanism can accurately and reliably sort fair, bad and non-tested components into three bins at a high speed without damaging the component.
